(19) United States
(12) Patent Application Publication
(10) Pub. No.: US 2026/0016723 A1
(43) Pub. Date: Jan. 15, 2026

(54) DISPLAY PANEL AND DISPLAY DEVICE

(71) Applicants: Wuhan BOE Optoelectronics Technology Co., Ltd., Wuhan, Hubei (CN); BOE Technology Group Co., Ltd., Beijing (CN)

(72) Inventors: Wei WU, Beijing (CN); Qi CHEN, Beijing (CN); Mengbo PAN, Beijing (CN); Junfeng DAI, Beijing (CN); Xiang LIU, Beijing (CN); Yuan TONG, Beijing (CN); Dang ZHANG, Beijing (CN); Hao ZHANG, Beijing (CN); Yiyi ZHANG, Beijing (CN); Yichen ZHOU, Beijing (CN); Taohe ZHU, Beijing (CN)

(21) Appl. No.: 18/992,507

(22) PCT Filed: Mar. 13, 2024
(86) PCT No.: PCT/CN2024/081519

§ 371 Date: Jan. 8, 2025

(30) Foreign Application Priority Data
Apr. 28, 2023 (CN) 202310478738.8

(51) Int. Cl. G02F 1/1339; G02F 1/1337; G02F 1/1362; H10D 86/40

(52) U.S. Cl. CPC G02F 1/1339; G02F 1/1337; G02F 1/136286; H10D 86/441

(57) ABSTRACT

A display panel and a display device are provided. The display panel includes: an opposite substrate and a display substrate arranged opposite to each other, and multiple support pillars between the opposite substrate and the display substrate. The display substrate includes a display area and a non-display area surrounding the display area. The non-display area includes a first wiring area. The multiple support pillars include first support pillars in the display area and second support pillars in the non-display area. Partial support pillars corresponding to the first wiring area among the second support pillars extend in a direction perpendicular to an extending direction of the side edge of the first wiring area.

### CROSS-REFERENCE TO RELATED APPLICATIONS

This application claims priority to Chinese Patent Application No. 202310478738.8, filed with the China National Intellectual Property Administration on Apr. 28, 2023 and entitled “Display Panel and Display Device”, the entire contents of which are incorporated herein by reference.

### TECHNICAL FIELD

The present disclosure relates to the field of display technology, and in particular to a display panel and a display device.

### BACKGROUND

As people's requirements for image quality of LCD screens become higher and higher, improving display quality of products has become a top priority for panel companies. How to solve the problem of yellowing in local areas of LCD panels has become the key to improving image quality.

### SUMMARY

The present disclosure provides a display panel and a display device. The scheme is as follows.

Embodiments of the present disclosure provide a display panel, including:
an opposite substrate and a display substrate arranged opposite to each other, and a plurality of support pillars between the opposite substrate and the display substrate.

The display substrate includes a display area and a non-display area surrounding the display area. The non-display area includes a first wiring area. The plurality of support pillars include first support pillars in the display area and second support pillars in the non-display area. Partial support pillars corresponding to the first wiring area among the second support pillars extend along a direction perpendicular to an extending direction of a side edge of the first wiring area.

Optionally, in embodiments of the present disclosure, all of the second support pillars extend in the same direction.

Optionally, in embodiments of the present disclosure, the display substrate further includes an alignment layer extending from the display area to the non-display area. The alignment layer partially overlaps with the first wiring area.

Optionally, in embodiments of the present disclosure, an orthographic projection of the partial support pillars on the display substrate is completely in an overlapping area between the alignment layer and the first wiring area.

Optionally, in embodiments of the present disclosure, the distribution density of the partial support pillars in the overlapping area is less than the distribution density of support pillars other than the partial support pillars among the second support pillars.

Optionally, in embodiments of the present disclosure, the first wiring area includes a plurality of first wiring lines extending along the extending direction and a plurality of second wiring lines extending perpendicular to the extending direction. The orthographic projection of the partial support pillar on the display substrate is completely in the region between two adjacent second wiring lines.

Optionally, in embodiments of the present disclosure, the partial support pillar is a semi-cylinder. The maximum cross-sectional diameter of the semi-cylinder along a plane parallel to the plane where the display substrate is located is smaller than the distance between two adjacent first wirings and smaller than the distance between two adjacent second wirings.

Optionally, in embodiments of the present disclosure, the display substrate also includes a second wiring area alternately arranged with the first wiring area along the extending direction. In the second wiring area, the distance between the boundary of the alignment layer close to the side edge and the display area is greater than 1.2 μm, and less than the distance between the display area and the side edge. In the first wiring area, the distance between the boundary of the alignment layer close to the side edge and the display area is greater than the distance between the side of the partial support pillars close to the side edge and the display area, and less than the distance between the display area and the side edge.

Optionally, in embodiments of the present disclosure, the orthographic projection of the partial support pillars on the display substrate does not overlap with the overlapping area between the alignment layer and the first wiring area.

Optionally, in embodiments of the present disclosure, the display panel further includes a frame sealant close to the side edge. The partial support pillars are located between the overlapping area and the frame sealant.

Optionally, in embodiments of the present disclosure, the display substrate further includes a second wiring area alternately arranged with the first wiring area along the extending direction. The second wiring area includes a first row of support pillars and a second row of support pillars extending perpendicular to the extending direction and arranged along the extending direction. The first row of support pillars and the second row of support pillars are sequentially arranged close to the frame sealant. The partial support pillars include a third row of support pillars and a fourth row of support pillars extending perpendicular to the extending direction and arranged along the extending direction. The third row of support pillars and the fourth row of support pillars are sequentially arranged close to the frame sealant. The distance between two adjacent support pillars in the second row of support pillars is smaller than the distance between the overlapping area and the side of the third row of support pillars away from the frame sealant. The fourth row of support pillars are separated from the frame sealant by a preset distance.

Optionally, in the embodiment of the present disclosure, in the first wiring area and the second wiring area, a distance between a boundary of the alignment layer close to the side and the display area ranges from 1.2 μm to 2.8 μm.

Optionally, in embodiments of the present disclosure, the first support pillar extends along an extending direction parallel to a side edge of the display substrate where the first wiring area is arranged.

Accordingly, embodiments of the present disclosure provide a display device, including:
a display panel as described in any one of the above embodiments.

### BRIEF DESCRIPTION OF DRAWINGS

FIG. 1 is a schematic diagram showing yellowing at a fixed position of the Data Pad (DP) side of a liquid crystal panel product in the related art based on that the thickness of a polyimide (PI) film of the liquid crystal panel product is 1000 angstroms.

FIG. 2 is a schematic diagram showing relative positions of the Post Spacer (PS) Bar and the fan-shaped metal wiring area at the Thin Film Transistor (TFT) side after box alignment in the liquid crystal panel product.

FIG. 3 is a schematic diagram of a cross-sectional structure along the direction indicated by MM in FIG. 2.

FIG. 4 is a schematic diagram of the surface morphology of the PS Bar in the yellowing area of the liquid crystal panel product shown in FIG. 1.

FIG. 5 is a schematic diagram of a top view of a display panel provided in an embodiment of the present disclosure.

FIG. 6 is a schematic diagram of a cross-sectional structure along the direction indicated by NN in FIG. 5.

FIG. 7 is a schematic diagram of a distribution of second support pillars in a display panel provided by an embodiment of the present disclosure.

FIG. 8 is a schematic diagram of a distribution of second support pillars in a display panel provided by an embodiment of the present disclosure.

FIG. 9 is a schematic diagram of a top view of a display substrate in a display panel provided by an embodiment of the present disclosure.

FIG. 10 is a schematic diagram showing a distribution of support pillars corresponding to a first wiring area in a display panel provided by an embodiment of the present disclosure.

FIG. 11 is a schematic diagram showing a distribution of support pillars corresponding to a first wiring area in a display panel provided by an embodiment of the present disclosure.

FIG. 12 is a schematic diagram showing a distribution of support pillars corresponding to a first wiring area in a display panel provided by an embodiment of the present disclosure.

FIG. 13 is a schematic diagram of a partial cross-sectional structure along the direction OO in FIG. 5.

FIG. 14 is a schematic diagram of a top view of a display substrate in a display panel provided by an embodiment of the present disclosure.

FIG. 15 is a schematic diagram of upper and lower limits of PI EM control of a display substrate in a display panel provided by an embodiment of the present disclosure.

FIG. 16 is a schematic diagram showing a distribution of support pillars corresponding to a first wiring area in a display panel provided by an embodiment of the present disclosure.

### DETAILED DESCRIPTION

In order to make the purpose, technical solution and advantages of the embodiments of the present disclosure more clear, the technical solution of the embodiments of the present disclosure will be clearly and completely described below in conjunction with the drawings of the embodiments of the present disclosure. Obviously, the described embodiments are only part of the embodiments of the present disclosure, rather than all the embodiments.

Furthermore, the embodiments in the present disclosure and the features in the embodiments may be combined with each other without conflict. Based on the described embodiments of the present disclosure, all other embodiments obtained by those of ordinary skill in the art without creative work are within the scope of protection of the present disclosure.

Unless otherwise defined, technical or scientific terms used in the present disclosure should have the common meanings understood by a person having ordinary skills in the field to which the present disclosure belongs. The words “include” or “comprise” and the like used in the present disclosure mean that the elements or objects preceding the words include the elements or objects listed after the words and their equivalents, but do not exclude other elements or objects.

It should be noted that the size and shape of each figure in the accompanying drawings do not reflect the actual proportion, and the purpose is only to illustrate the content of the present invention. And the same or similar reference numerals throughout represent the same or similar elements or elements with the same or similar functions.

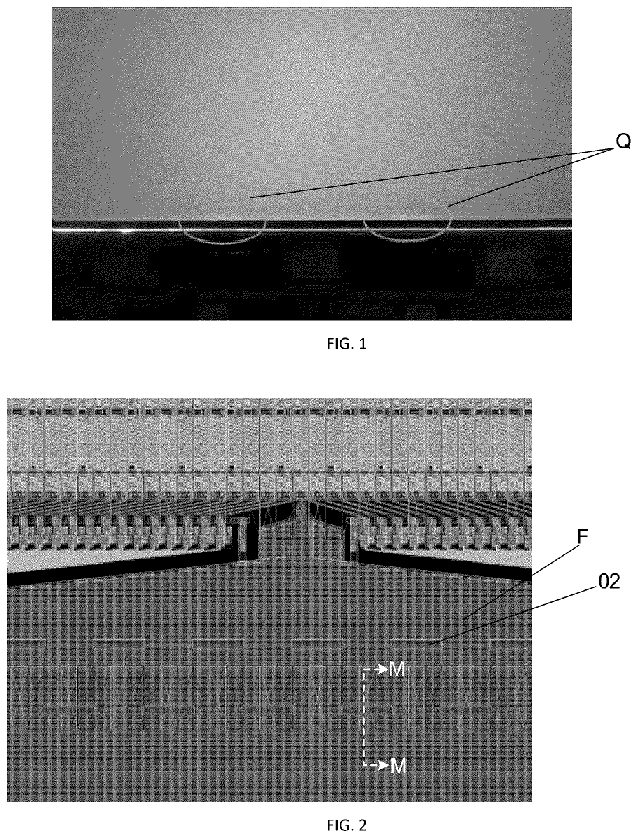

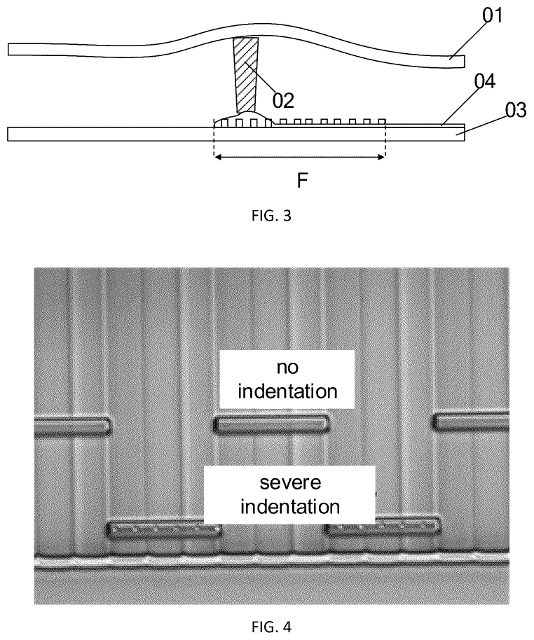

In the related art, the inventors discovered through actual research that during the development and mass production of 65-inch 4K 144 Hz LCD products, yellowing at the data pad (DP) side under the L127 screen occurs in the module segment, which is a serious phenomenon with a high rate of occurrence, and severely affects the display quality and out-going grade. FIG. 1 is a schematic diagram showing yellowing at a fixed position of the DP side (as shown in area Q in FIG. 1) based on that the thickness of the PI (polyimide) film in the certain liquid crystal panel product is 1000 angstroms. By disassembling the screen and observing the color filter (CF) side 01 of the LCD panel with a microscope, it was found that the yellowing position exactly matches the position of the spacer (Post Spacer Bar, PS Bar) 02. FIG. 2 is a schematic diagram showing the relative positions of the PS Bar 02 and the fan-shaped metal wiring area F at the TFT side 03 after the box alignment. FIG. 3 is a schematic diagram of a cross-sectional structure along the direction indicated by line MM in FIG. 2. In addition, the position at the TFT side 03 corresponding to the PS Bar 02 is the diffusion edge of the PI droplet used to prepare the alignment layer. Uneven diffusion is prone to occur here, resulting in abnormal thickness of the

PI film. The PI film 04 with the abnormal thickness is superimposed on PS Bar 02, resulting in abnormally high box thickness at the corresponding position, which leads to the occurrence of yellowing.

In order to further verify the yellowing caused by the superposition of PS Bar 02 at the CF side 01 and PI film 04 at the TFT side 03, the inventors observed the CF side 01 of the liquid crystal panel product with severe yellowing and 1000 angstroms of PI thickness through a Scanning Electron Microscope (SEM). The surface morphology of PS Bar 02 in the corresponding yellowing area is shown in FIG. 4. As shown in FIG. 4, the surface of the PS Bar in the first row is smooth and flat, while the PS Bar in the second row has severe indentations, indicating that the PS Bar 02 at the CF side 01 and the PI film 04 at the TFT side 03 have a mutual squeezing force. Based on this, the inventors believe that the overlap between the PS Bar 02 at the CF side 01 and the PI film 04 at the TFT side 03 causes the local box thickness to be abnormally high, thereby causing the yellowing phenomenon.

In view of this, embodiments of the present disclosure provide a display panel and a display device for solving the DP yellowing problem.

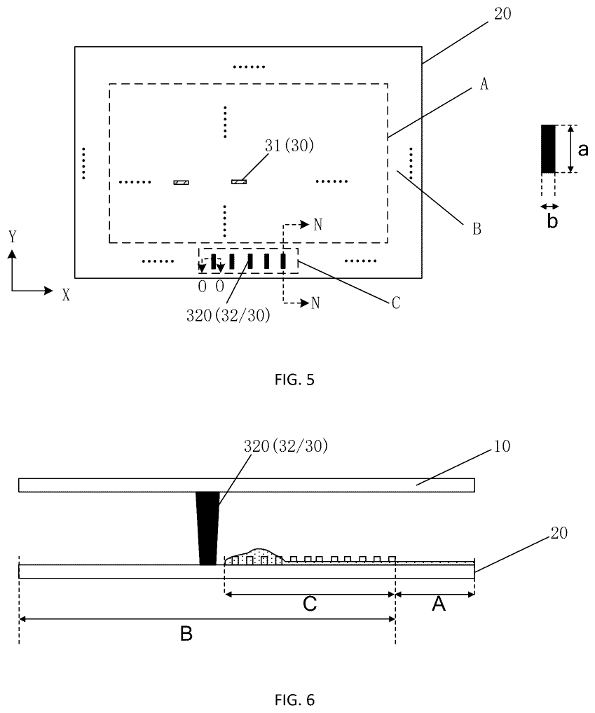

As shown in combination with FIG. 5 and FIG. 6, FIG. 5 is a schematic diagram of a top view of a display panel provided in the present disclosure, and FIG. 6 is a schematic diagram of a cross-sectional structure along the direction indicated by NN in FIG. 5.

Specifically, the display panel includes: an opposite substrate 10 and a display substrate 20 arranged opposite to each other, and a plurality of support pillars 30 between the opposite substrate 10 and the display substrate 20.

The display substrate 20 includes a display area A and a non-display area B surrounding the display area A. The non-display area B includes first wiring area(s) C. The plurality of support pillars 30 include first support pillar(s) 31 in the display area A and second support pillar(s) 32 in the non-display area B. Partial support pillar(s) 320 corresponding to the first wiring area C among the second support pillar(s) 32 is/are disposed along a direction perpendicular to an extending direction of a side edge of the first wiring area C.

In an implementation process, the display panel includes: an opposite substrate 10 and a display substrate 20 arranged opposite to each other, and a plurality of support pillars 30 between the opposite substrate 10 and the display substrate 20. The display substrate 20 is a TFT substrate, and the opposite substrate 10 is a CF substrate. The quantity of the plurality of support pillars 30 can be set according to actual application requirements and is not limited here. Moreover, the display substrate 20 includes a display area A and a non-display area B surrounding the display area A. The non-display area B includes first wiring area(s) C. FIG. 5 is a schematic diagram showing one distribution of the display area A, the non-display area B and the first wiring area C. Of course, the distribution of the display area A, the non-display area B and the first wiring area C may also be set according to actual application requirements, which is not limited here.

In addition, the plurality of support pillars 30 include first support pillar(s) 31 in the display area A and second support pillar(s) 32 in the non-display area B. That is, support pillar(s) 30 in the display area A is/are first support pillar(s) 31, and support pillar(s) 30 in the non-display area B is/are second support pillar(s) 32. It should be noted that there may be multiple first support pillars 31 and multiple second support pillars 32. The quantities of the first support pillar(s) 31 and the second support pillar(s) 32 can be set according to actual application requirements and are not limited here.

Moreover, partial support pillar(s) 320 corresponding to the first wiring area C among the second support pillar(s) 32 is/are disposed along a direction perpendicular to an extending direction of a side edge of the first wiring area C. Exemplarily, still in combination with FIG. 5, the first wiring area C is arranged at a long side of the display substrate. The direction indicated by the arrow X is the extending direction of the side edge of the first wiring area C, and the direction indicated by the arrow Y is the direction perpendicular to the extending direction of the side edge of the first wiring area C. The side of the display substrate where the first wiring area C is set is the long side, the partial support pillar(s) 320 corresponding to the first wiring area C among the second support pillar(s) 32 is/are disposed along a direction parallel to the extending direction of the short side of the display substrate. Exemplarily, the shape of a single support pillar in the partial support pillar(s) 320 is approximately a rectangular parallelepiped. When the shape of the orthographic projection of the single support pillar 320 on the display substrate 20 is a rectangle, the long side of the shape of the orthographic projection of the partial support pillar 320 on the display substrate 20 is perpendicular to the long side of the display substrate 20, and parallel to the short side of the display substrate 20. In this way, the probability of overlapping of the partial support pillar(s) 320 with the wiring node(s), formed by cross-linking of horizontal and vertical wiring lines in the first wiring area C, in the direction perpendicular to the long side direction of the display substrate 20 is reduced, thereby weakening the degree of overlapping between the partial support pillar(s) 320 and the aggregation part of PI used to prepare the alignment layer 40 subsequently, avoiding the yellowing problem caused by the overlap between the two. It should be noted that the long side of the display substrate 20 is arranged corresponding to the long side of the display panel, and the short side of the display substrate 20 is arranged corresponding to the short side of the display panel.

It should be noted that the arrangement of the first support pillar(s) 31 may refer to the technical implementation in the relevant technology and will not be described in detail here.

In embodiments of the present disclosure, all of the second support pillars 32 extend in the same direction.

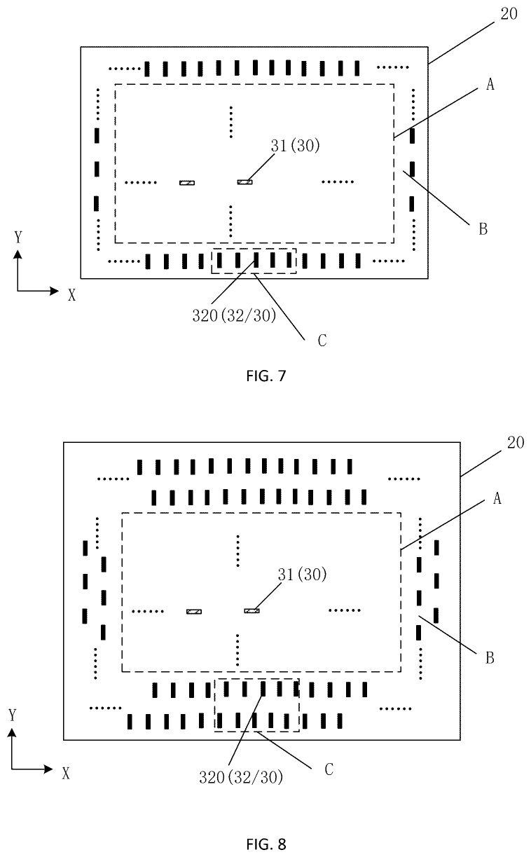

In exemplary embodiments, FIG. 7 is a schematic diagram of a distribution of the second support pillars 32 in the display panel. Specifically, all the second support pillars 32 extend along a direction perpendicular to the extending direction of the side edge of the display panel where the first wiring area C is arranged. It should be noted that, in exemplary embodiments shown in FIG. 7, the second support pillars 32 are disposed around the display area A for only one circle. In exemplary embodiments shown in FIG. 8, the second support pillars 32 include two circles, i.e., inner and outer circles, disposed around the display area A. Of course, the quantity of circles of the second support pillars 32 can also be set according to actual application needs, which is not limited here.

In embodiments of the present disclosure, the display substrate 20 further includes an alignment layer 40 extending from the display area A to the non-display area B. The alignment layer 40 partially overlaps with the first wiring area C.

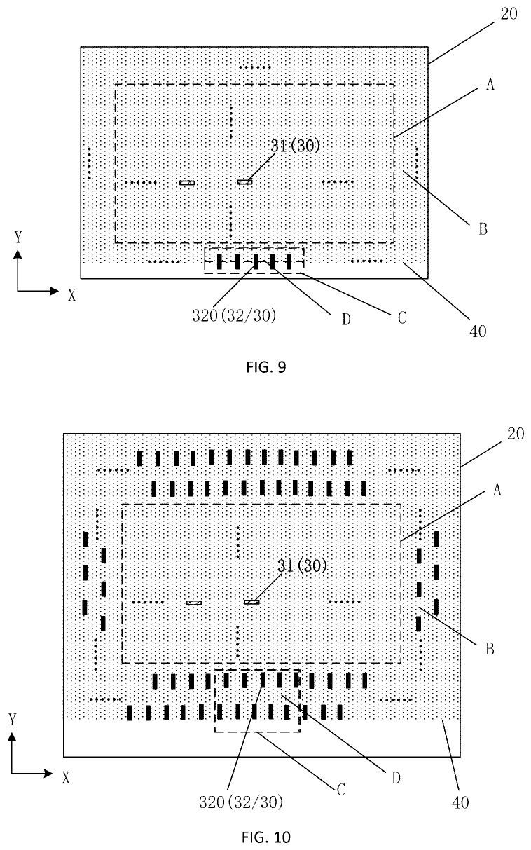

In exemplary embodiments, FIG. 9 is a schematic diagram of a top view of a display substrate 20. Specifically, the display substrate 20 further includes an alignment layer 40 extending from the display area A to the non-display area B. For example, the alignment layer 40 may be a polyimide (PI) film. In an implementation process, the display panel further includes a liquid crystal layer between the display substrate 20 and the opposite substrate 10. Accordingly, the display panel is a liquid crystal display panel. In an implementation process, the liquid crystal molecules in the liquid crystal layer are tilted at a preset angle through the pre-set alignment layer 40, thereby adjusting the light transmittance and ensuring the display effect of the display panel. In addition, the alignment layer 40 partially overlaps with the first wiring area C. Accordingly, there is an overlapping area D between the alignment layer 40 and the first wiring area C. An edge of the alignment layer 40 away from the display area A completely falls into the first wiring area C. In this way, when partial support pillars 320 extend along the direction perpendicular to the extending direction of the side edge of the display panel where the first wiring area C is arranged, the aggregation degree of the PI droplets used to prepare the alignment layer 40 in the first wiring area is weakened.

In embodiments of the present disclosure, the partial support pillars 320 may be distributed in the following ways, but are not limited to the following ways.

In exemplary embodiments, as shown in FIG. 10, the orthographic projection of the partial support pillars 320 on the display substrate 20 completely falls within the overlapping area D between the alignment layer 40 and the first wiring area C.

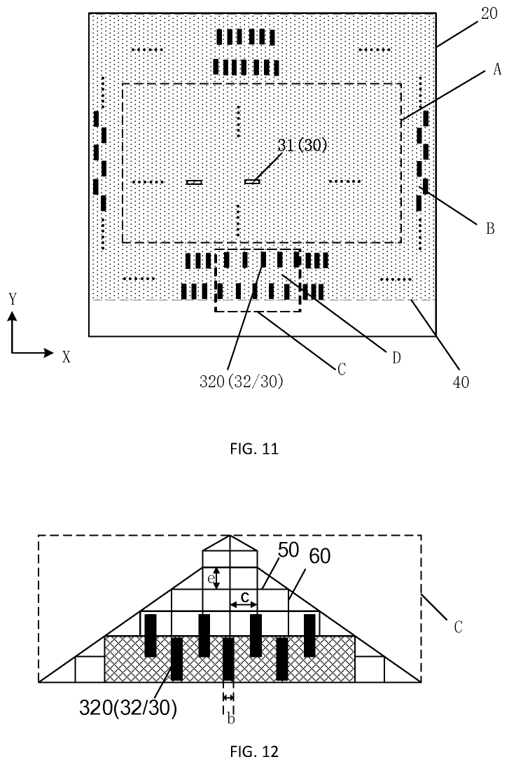

In exemplary embodiments, as shown in FIG. 11, the distribution density of the partial support pillars 320 in the overlapping area D is smaller than the distribution density of support pillars other than the partial support pillars 320 in the second support pillars 32. The values of the distribution density of the partial support pillars 320 in the overlapping area D and the distribution density of the support pillars other than the partial support pillars 320 in the second support pillars 32 can be set according to actual application needs and are not limited here. In this way, the probability of overlapping of the partial support pillars 320 with the aggregation part of PI used to prepare the alignment layer 40 is reduced, thereby avoiding the yellowing problem caused by the overlap between the two.

It should be noted that in the related art, the inventors studied the microscope images

at the TFT side and found that the aggregation of PI used to prepare the alignment layer 40 mostly occurred near the wiring nodes in the first wiring area C. In embodiments of the present disclosure, once the probability of overlapping of the partial support pillars 320 corresponding to the first wiring area C with the wiring nodes is reduced, the probability of overlapping of the partial support pillars 320 with the aggregation part of PI used to prepare the alignment layer 40 can be effectively reduced, thereby avoiding the yellowing problem caused by the overlap between the two.

In exemplary embodiments, the first wiring area C includes a plurality of first wiring lines 50 arranged along the extending direction and a plurality of second wiring lines 60 arranged perpendicular to the extending direction. The orthographic projection of the partial support pillar 320 on the display substrate 20 completely falls within the region between two adjacent second wiring lines 60.

In conjunction with the exemplary embodiments shown in FIG. 12, the first wiring area C includes a plurality of first wiring lines 50 (i.e., horizontal wiring lines) arranged along the extending direction, and a plurality of second wiring lines 60 (i.e., vertical wiring lines) arranged perpendicular to the extending direction. Moreover, the orthographic projection of the partial support pillar 320 on the display substrate 20 completely falls within the region between two adjacent second wiring lines 60. In this way, the probability of overlapping of the cross-linked nodes (i.e., wiring nodes) of the first wirings 50 and the second wirings 60 with the partial support pillars 320 is reduced. Accordingly, the probability of overlapping of the partial support pillars 320 with the aggregation part of PI used to prepare the alignment layer 40 is reduced, thereby avoiding the yellowing problem caused by the overlap between the two.

It should be noted that in the exemplary embodiments shown in FIG. 12, in order to clearly illustrate the positional relationship between the partial support pillars 320 and related wiring lines in the first wiring area C, only a partial structure of the alignment layer 40 is illustrated (as shown in the shaded portion in FIG. 12). In the exemplary embodiments, the shape of a single support pillar 320 is approximately a rectangular parallelepiped. The length of the shape of the orthographic projection of the single support pillar 320 on the display substrate 20 is ‘a’, and the width of the shape of the orthographic projection of the single support pillar 320 on the display substrate 20 is ‘b’. The shape of the orthographic projection is shown in FIG. 5. The spacing between two adjacent second wiring lines 60 is ‘c’. ‘b’ can be set to be smaller than ‘c’, thereby reducing the probability of overlapping of the single support pillar 320 with the aggregation part of PI used to prepare the alignment layer 40, and avoiding the yellowing problem caused by the overlap between the two.

In exemplary embodiments, the partial support pillar 320 is a semi-cylinder. The maximum cross-sectional diameter of the semi-cylinder along a plane parallel to a plane where the display substrate 20 is located is smaller than the distance between two adjacent first wiring lines 50 and smaller than the distance between two adjacent second wiring lines 60.

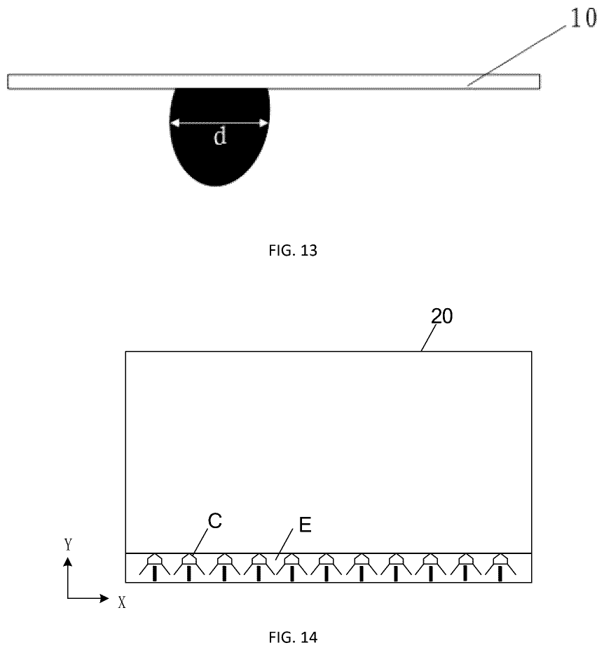

As shown in FIG. 13, FIG. 13 is a schematic diagram of a partial cross-sectional structure along the direction shown by OO in FIG. 5. Specifically, the partial support pillar 320 is a semi-cylinder. That is, a single support pillar 320 is set as a semi-cylinder. ‘d’ represents the maximum cross-sectional diameter of the semi-cylinder along a plane parallel to a plane where the display substrate 20 is located, ‘e’ represents the distance between two adjacent first wiring lines 50, and ‘c’ represents the distance between two adjacent second wiring lines 60. In an implementation process, d>e and d>c can be set for a single support pillar 320. That is, the maximum cross-sectional diameter of the semi-cylinder along the plane parallel to the plane where the display substrate 20 is located is smaller than the distance between two adjacent first wiring lines 50 and smaller than the distance between two adjacent second wiring lines 60. In this case, even if the orthographic projection of the partial support pillar(s) 320 on the display substrate 20 completely falls into the overlapping area D between the alignment layer 40 and the first wiring area C, by setting d>e and d>c for a single support pillar 320, the probability of accommodating the single support pillar 320 with a semi-cylindrical shape within the grid divided by the multiple first wiring lines 50 and the multiple second wiring lines 60 is increased to a certain extent, thereby reducing the probability of overlapping of the partial support pillar(s) 320 with the wiring nodes in the first wiring area C. Further, since the cross-sectional area of the end of the semi-cylinder facing away from the opposite substrate 10 along the plane parallel to the display substrate 20 is smaller, the contact area between the single support pillar 320 and the first wiring area C is reduced, thereby reducing the film thickness caused by contact and avoiding the yellowing problem.

In embodiments of the present disclosure, the display substrate 20 also includes second wiring area(s) E alternately arranged with the first wiring area(s) C along the extending direction. In the second wiring area E, the distance between the boundary of the alignment layer 40 close to the side edge and the display area A is greater than 1.2 μm, and is less than the distance between the display area A and the side edge. In the first wiring area C, the distance between the boundary of the alignment layer 40 close to the side edge and the display area A is greater than the distance between the side of the partial support pillar(s) 320 close to the side edge and the display area A, and is less than the distance between the display area A and the side edge.

In an implementation process, in combination with a top view of a display substrate 20 shown in FIG. 14, the display substrate 20 further includes second wiring areas E alternately arranged with the first wiring areas C along the extending direction. FIG. 14 is a schematic diagram showing a distribution of the first wiring areas C and the second wiring areas E. Of course, the distribution of the first wiring areas C and the second wiring areas E can also be set according to actual application needs, which is not limited here. It should be noted that the first wiring area C is used to introduce a common voltage, and the first wiring area C is also called a fan-shaped area. The first wiring area C includes a plurality of first wiring lines 50 arranged along the extending direction and a plurality of second wiring lines 60 perpendicular to the extending direction. The plurality of first wiring lines 50 and the plurality of second wiring lines 60 are interconnected to form a plurality of grids. The second wiring area E is used for externally connecting source-drain signal voltages and gate signal voltages, and the second wiring area E is also called a non-fan-shaped area. The second wiring area E includes a plurality of third wiring lines extending in the same direction. For the structural arrangement of the first wiring area C and the second wiring area E, reference may be made to the structural description of the fan-shaped area and the non-fan-shaped area in the related technical field, which will not be described in detail here.

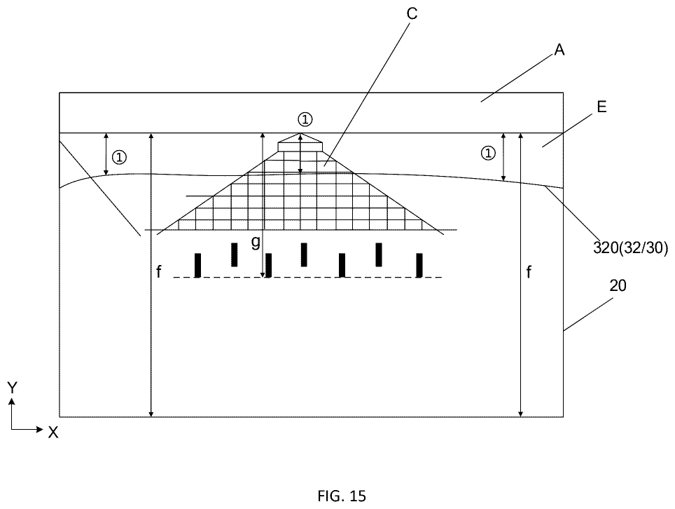

In an actual process of preparing the display substrate 20, it is necessary to adopt a PI EM control method for the DP side of the display substrate 20. The PI EM control value is defined as the distance from the outermost edge of the alignment layer 40 to the first sub-pixel in the display area A. Specifically, in the second wiring area E, the distance between the boundary of the alignment layer 40 close to the side edge and the display area A is greater than 1.2 μm. That is, the lower limit of PI EM control value is 1.2 μm. The distance between the boundary of the alignment layer 40 close to the side edge and the display area A is smaller than the distance between the display area A and the side edge. Exemplarily, the upper limit of PI EM control value is the distance between the display area A and the bonding area of the printed circuit board (PCB) outside the DP. As shown in FIG. 15, \textcircled{1}represents the PI EM control value, and ‘f’ represents the lower limit of the PI EM control value in the second wiring area E.

In addition, in the first wiring area C, the distance between the boundary of the alignment layer 40 close to the side edge and the display area A is greater than the distance between the side of partial support pillars 320 and the display area A. The lower limit of PI EM control value is the distance between the side of partial support pillars 320 and the display area A, which is shown by ‘g’ in FIG. 15. The distance between the boundary of the alignment layer 40 close to the side edge and the display area A is less than the distance between the display area A and the side edge. Exemplarily, the upper limit of PI EM control value is the distance between the display area A and the PCB Bonding area outside the DP. Still in combination with the exemplary embodiments shown in FIG. 15, in the first wiring area C, the lower limit of PI EM control value is still ‘f’. It should be noted that the PI EM control values in the second wiring area E and the first wiring area C can be set according to actual application needs and are not limited here.

In an actual process of preparing the opposite substrate 10, firstly, a PI wet film is evenly coated on the entire substrate in a certain pattern, and then, the corresponding alignment layer 40 is formed through pre-curing and curing. During the preparation process of the alignment layer 40 of the entire opposite substrate 10, no PI EM control is required. After PI coating and curing are performed on the display substrate 20 and the opposite substrate 10 respectively, subsequent processes such as rubbing, box alignment, and cutting can be performed to prepare the required display panel. The preparation process can be implemented by referring to the technology in the relevant technical field, which will not be described in detail here.

In exemplary embodiments, the orthographic projection of the partial support pillars 320 on the display substrate 20 does not overlap with the overlapping area D between the alignment layer 40 and the first wiring area C.

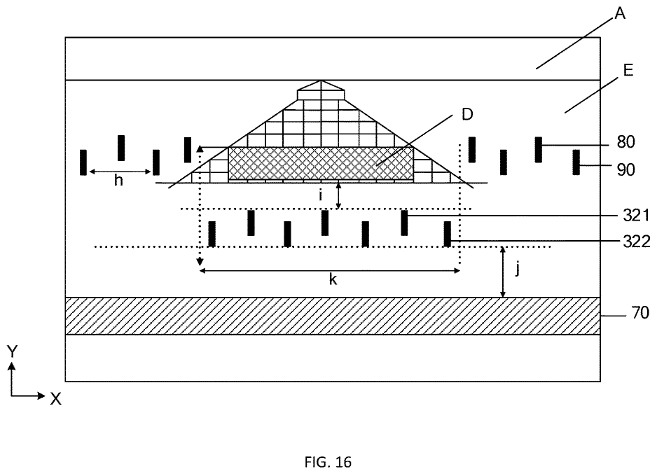

In conjunction with the exemplary embodiments shown in FIG. 16, the orthographic projection of the partial support pillars 320 on the display substrate 20 does not overlap with the overlapping area D (the entire overlapping area is not shown in the figure) between the alignment layer 40 and the first wiring area C. Exemplarily, the partial support pillars 320 are staggered in a region between a boundary of the alignment layer 40 close to the side edge and the side edge. In this way, the problem of film thickness caused by the overlapping of the partial support pillars 320 with the overlapping area D is avoided.

In embodiments of the present disclosure, still in combination with FIG. 16, the display panel further includes a frame sealant 70 close to the side edge. The partial support pillars 320 are located between the overlapping area D and the frame sealant 70. In this way, the film thickness problem caused by the overlapping of the partial support pillars 320 with the overlapping area D is avoided while the packaging performance of the display panel is taken into consideration.

In embodiments of the present disclosure, the display substrate 20 also includes second wiring areas E alternately arranged with the first wiring areas C along the extending direction. The second wiring area E includes a first row of support pillars 80 and a second row of support pillars 90 extending perpendicular to the extending direction and arranged along the extending direction. The first row of support pillars 80 and the second row of support pillars 90 are arranged in sequence close to the frame sealant 70. The partial support pillars 320 include a third row of support pillars 321 and a fourth row of support pillars 322 extending perpendicular to the extending direction and arranged along the extending direction. The third row of support pillars 321 and the fourth row of support pillars 322 are arranged in sequence close to the frame sealant 70. The distance between two adjacent support pillars in the second row of support pillars 90 is greater than the distance between the overlapping area D and the side of the third row of support pillars 321 away from the frame sealant 70. The fourth row of support pillars 322 are separated from the frame sealant 70 by a preset distance.

Still in combination with the exemplary embodiments shown in FIG. 16, the display substrate 20 also includes second wiring areas E alternately arranged with the first wiring areas C along the extending direction. The second wiring area E includes a first row of support pillars 80 and a second row of support pillars 90 extending perpendicular to the extending direction and arranged along the extending direction. The first row of support pillars 80 and the second row of support pillars 90 are sequentially arranged close to the frame sealant 70. The first row of support pillars 80 and the second row of support pillars 90 are staggered with each other.

The first row of support pillars 80 is located on the side of the second row of support pillars 90 away from the side edge of the display substrate 20. Moreover, the partial support pillars 320 include a third row of support pillars 321 and a fourth row of support pillars 322 extending perpendicularly to the extending direction and arranged along the extending direction. The third row of support pillars 321 and the fourth row of support pillars 322 are arranged in sequence close to the frame sealant 70. The third row of support pillars 321 and the fourth row of support pillars 322 are staggered with each other. The fourth row of support pillars 322 is located on a side of the third row of support pillars 321 close to the side edge of the display substrate 20. In addition, the distance between two adjacent support pillars in the second row of support pillars 90 is greater than the distance between the overlapping area D and the side of the third row of support pillars 321 away from the frame sealant 70. The fourth row of support pillars 322 is at a preset distance from the frame sealant 70. Still in combination with FIG. 16, ‘h’ represents the distance between two adjacent support pillars in the second row of support pillars 90, ‘i’ represents the distance between the overlapping area D and the side of the third row of support pillars 321 away from the frame sealant 70, and ‘j’ represents the preset distance between the fourth row of support pillars 322 and the frame sealant 70. In this way, the probability of overlapping of the third row of support pillars 321 and the fourth row of support pillars 322 with the first wiring area C is reduced, thereby avoiding the yellowing problem caused by the overlap.

It should be noted that, still in combination with the exemplary embodiments shown in FIG. 16, for a single first wiring area C, the third row of support pillars 321 and the fourth row of support pillars 322 in the first wiring area C have a staggered width ‘k’ along the a direction parallel to the extending direction of the side edge of the display substrate 20 where the first wiring area C is arranged. The value of the staggered width ‘k’ is equal to the width formed by the corresponding PI EM of the first wiring area C. In an implementation process, the value of the corresponding distance can be set according to actual application needs, and is not limited here.

In embodiments of the present disclosure, in the first wiring area C and the second wiring area E, the distance between the boundary of the alignment layer 40 close to the side edge and the display area A ranges from 1.2 μm to 2.8 μm.

In embodiments of the present disclosure, the first support pillar 31 is arranged along a direction parallel to the extending direction of the side edge of the display substrate 20 where the first wiring area C is arranged.

Still referring to the exemplary embodiments shown in FIG. 5, the second support pillars 32 are arranged vertically, and the first support pillars 31 are arranged horizontally. Of course, the arrangement of the first support pillars 31 and the second support pillars 32 may also be set according to actual applications, which will not be described in detail here.

It should be noted that, in embodiments of the present disclosure, in addition to the aforementioned arrangement, the second support pillars 32 may also be arranged in other ways as required, which will not be described in detail herein. Moreover, in addition to the above-mentioned related film layers, the display panel provided in the embodiments of the present disclosure may also be provided with other film layers according to actual application requirements, and the implementation method thereof will not be described in detail here.

Based on the same disclosed concept, embodiments of the present disclosure further provide a display device, which includes the above-mentioned display panel provided by the embodiments of the present disclosure. Since the principle of solving the problem by the display device is similar to the principle of solving the problem by the above-mentioned display panel, the implementation of the display device provided in the embodiments of the present disclosure can refer to the implementation of the above-mentioned display panel, and the repeated parts will not be repeated.

In some embodiments, in some embodiments, the above-mentioned display device provided by the embodiments of the present disclosure can be applied to any product or component with a display function, such as mobile phones, tablet computers, televisions, monitors, laptop computers, digital photo frames, navigators, smart watches, fitness wristbands, personal digital assistants, etc.

Optionally, the display device provided in the embodiments of the present disclosure is a liquid crystal display screen. The liquid crystal display screen may include a backlight module and a display panel at the light emitting side of the backlight module. The display panel includes a display substrate 20 and an opposite substrate 10 arranged opposite to each other, a liquid crystal layer between the display substrate 20 and the opposite substrate 10, a frame sealant surrounding the liquid crystal layer between the display substrate 20 and the opposite substrate 10, a first alignment layer located on a side of the display substrate 20 close to the liquid crystal layer, a second alignment layer located on a side of the opposite substrate 10 close to the liquid crystal layer, a first polarizer located on a side of the display substrate 20 away from the liquid crystal layer, and a second polarizer located on a side of the opposite substrate 10 away from the liquid crystal layer, etc. The backlight module can be a direct-lit backlight module or an edge-lit backlight module. The backlight module may include a light source, stacked reflective sheets, a light guide plate, a diffusion sheet, and a prism group, etc. The light source may be a light emitting diode (LED), such as a micro light emitting diode (Mini LED, Micro LED, etc.).

In some embodiments, the above-mentioned display device provided by the embodiments of the present disclosure may include but is not limited to: a radio frequency unit, a network module, an audio output & input unit, a sensor, a display unit, a user input unit, an interface unit, a control chip and other components. Optionally, the control chip is a central processing unit, a digital signal processor, a system on chip (SoC), etc. For example, the control chip may also include a memory, a power module, etc., and realize power supply and signal input and output functions through additionally provided wires, signal lines, etc. For example, the control chip may also include hardware circuits and computer executable codes. Hardware circuits may include conventional very large scale integration (VLSI) circuits or gate arrays and existing semiconductors such as logic chips, transistors, etc., or other discrete components. Hardware circuits may also include field programmable gate arrays, programmable array logic, programmable logic devices, etc.

In addition, those skilled in the art will appreciate that the above structure does not constitute a limitation on the above display device provided in the embodiments of the present disclosure. In other words, the above display device provided in the embodiments of the present disclosure may include more or fewer of the above components, or may combine certain components, or may use different component arrangements.

Although the present disclosure has described preferred embodiments, it should be understood that those skilled in the art may make various changes and modifications to the embodiments of the present disclosure without departing from the spirit and scope of the embodiments of the present disclosure. Thus, if these modifications and variations of the embodiments of the present disclosure fall within the scope of the claims of the present disclosure and their equivalents, the present disclosure is also intended to include these modifications and variations.

1. A display panel, comprising:
an opposite substrate and a display substrate arranged opposite to each other; and
a plurality of support pillars between the opposite substrate and the display substrate;
wherein, the display substrate comprises:
a display area, and
a non-display area surrounding the display area,
wherein the non-display area comprises a first wiring area;
the plurality of support pillars comprises:
first support pillars in the display area, and
second support pillars in the non-display area;
wherein partial support pillars corresponding to the first wiring area among the second support pillars extend along a direction perpendicular to an extending direction of a side edge of the first wiring area.

2. The display panel according to claim 1, wherein all of the second support pillars extend in the same direction.

3. The display panel according to claim 2, wherein the display substrate further comprises:
an alignment layer extending from the display area to the non-display area;
wherein the alignment layer partially overlaps with the first wiring area.

4. The display panel according to claim 3, wherein an orthographic projection of the partial support pillars on the display substrate is completely in an overlapping area between the alignment layer and the first wiring area.

5. The display panel according to claim 4, wherein a distribution density of the partial support pillars in the overlapping area is less than a distribution density of support pillars other than the partial support pillars among the second support pillars.

6. The display panel according to claim 5, wherein the first wiring area comprises:
a plurality of first wiring lines extending along the extending direction; and
a plurality of second wiring lines extending perpendicular to the extending direction;
wherein an orthographic projection of a partial support pillar on the display substrate is completely in a region between two adjacent second wiring lines.

7. The display panel according to claim 6, wherein the partial support pillar is a semi-cylinder, and a maximum cross-sectional diameter of the semi-cylinder along a plane parallel to a plane where the display substrate is located is smaller than a distance between two adjacent first wirings, and smaller than a distance between two adjacent second wirings.

8. The display panel according to claim 3, wherein the display substrate further comprises:
a second wiring area arranged alternately with the first wiring area along the extending direction;
wherein in the second wiring area, a distance between a boundary of the alignment layer close to the side edge and the display area is greater than 1.2 μm, and is smaller than a distance between the display area and the side edge;
in the first wiring area, the distance between the boundary of the alignment layer close to the side edge and the display area is greater than a distance between a side of the partial support pillars close to the side edge and the display area, and is smaller than the distance between the display area and the side edge.

9. The display panel according to claim 3, wherein an orthographic projection of the partial support pillars on the display substrate does not overlap with an overlapping area between the alignment layer and the first wiring area.

10. The display panel according to claim 9, further comprising:
a frame sealant close to the side edge,
wherein the partial support pillars are between the overlapping area and the frame sealant.

11. The display panel according to claim 10, wherein the display substrate further comprises:
a second wiring area arranged alternately with the first wiring area along the extending direction;
wherein the second wiring area comprises:
a first row of support pillars and a second row of support pillars extending perpendicular to the extending direction and arranged along the extending direction,
wherein the first row of support pillars and the second row of support pillars are sequentially arranged close to the frame sealant;
the partial support pillars comprise:
a third row of support pillars and a fourth row of support pillars extending perpendicular to the extending direction and arranged along the extending direction,
wherein the third row of support pillars and the fourth row of support pillars are sequentially arranged close to the frame sealant;
a distance between two adjacent support pillars in the second row of support pillars is greater than a distance between the overlapping area and a side of the third row of support pillars away from the frame sealant, and the fourth row of support pillars are separated from the frame sealant by a preset distance.

12. The display panel according to claim 11, wherein in the first wiring area and the second wiring area, a distance between a boundary of the alignment layer close to the side edge and the display area ranges from 1.2 μm to 2.8 μm.

13. The display panel according to claim 1, wherein the first support pillar extends along a direction parallel to a side edge of the display substrate where the first wiring area is arranged.

14. A display device, comprising:
the display panel according to claim 1.
